(19) United States
(12) Patent Application Publication
(10) Pub. No.: US 2020/0279943 A1
(43) Pub. Date: Sep. 3, 2020

(54) DUAL SILICIDE WRAP-AROUND CONTACTS FOR SEMICONDUCTOR DEVICES

(71) Applicant: Tokyo Electron Limited, Tokyo (JP)

(72) Inventor: Hiroaki Niimi, Albany, NY (US)

(21) Appl. No.: 16/803,995

(22) Filed: Feb. 27, 2020

Related U.S. Application Data
(60) Provisional application No. 62/812,133, filed on Feb. 28, 2019.

(51) Int. Cl. H01L 29/78; H01L 21/285; H01L 21/8234; H01L 21/3205; H01L 29/51; H01L 29/417; H01L 29/66

(52) U.S. Cl. CPC H01L 29/785; H01L 21/28568; H01L 21/823418; H01L 2029/7858; H01L 29/517; H01L 29/41791; H01L 29/66795; H01L 21/32053

(57) ABSTRACT

Low-resistivity dual silicide contacts for aggressively scaled semiconductor devices. A semiconductor device includes a first raised feature in a n-type channel field effect transistor (NFET) region on a substrate, a first n-type doped epitaxial semiconductor material wrapped around the first raised feature, a first metal silicide contact layer wrapped around the first n-type doped epitaxial semiconductor material, a second raised feature in p-type channel field effect transistor (PFET) region on the substrate, a second p-type epitaxial semiconductor material wrapped around the second raised feature, and a second metal silicide contact layer wrapped around the second p-type doped epitaxial semiconductor material. The first metal silicide contact layer can include a titanium silicide and the second metal silicide contact layer can include a ruthenium silicide.

### CROSS-REFERENCE TO RELATED APPLICATIONS

This application is related to and claims priority to U.S. Provisional Patent Application Ser. No. 62/812,133 filed on Feb. 28, 2019, the entire contents of which are herein incorporated by reference.

### FIELD OF THE INVENTION

The present invention relates to semiconductor devices and methods for manufacturing those devices, and more particularly, to low-resistivity dual silicide contacts for aggressively scaled devices.

### BACKGROUND OF THE INVENTION

Current and future generations of metal-oxide-semiconductor field effect transistors (MOSFETs) require tight control of parasitic capacitance while simultaneously optimizing metal-semiconductor contact resistance. Source and drain contact resistivity is one of the critical parameter that needs to be addressed to improve performance of scaled FinFETs and silicon nanowire/nanosheet devices. The adoption of ultra-thin transistor body structures such as FinFET and fully depleted silicon-on-insulator (FDSOI) has exacerbated the problem of contact resistance for logic manufacturing.

### SUMMARY OF THE INVENTION

Semiconductor devices and methods for manufacturing those devices are described in several embodiments. In some embodiments, low-resistivity dual silicide contacts for field effect transistors (FETs) are described, where a first metal silicide contact layer in a n-type channel field effect transistor (NFET) region includes a titanium silicide and a second metal silicide contact layer in a p-type channel field effect transistor (PFET) region includes a ruthenium silicide.

According to one embodiment, a semiconductor device includes a first raised feature in a NFET region on a substrate, a first n-type doped epitaxial semiconductor material wrapped around the first raised feature, a first metal silicide wrapped around the first n-type doped epitaxial semiconductor material, a second raised feature in a PFET region on the substrate, a second p-type doped epitaxial semiconductor material wrapped around the second raised feature, and a second metal silicide wrapped around the second p-type doped epitaxial semiconductor material.

According to another embodiment, a semiconductor device includes a first raised Si feature in a NFET region on a substrate, a first n-type doped epitaxial semiconductor material wrapped around the first raised Si feature, the first N-TYPE doped epitaxial semiconductor material containing Si:P or Si:As, a titanium silicide wrapped around the first n-type doped epitaxial semiconductor material, a second raised Si feature in a PFET region on the substrate, a second p-type doped epitaxial semiconductor material wrapped around the second raised feature, the second doped epitaxial semiconductor material containing Si:B or SiGe:B, and a ruthenium silicide wrapped around the second p-type doped epitaxial semiconductor material.

According to one embodiment, a method of forming a semiconductor device includes growing a first n-type doped epitaxial semiconductor material on a first raised feature in a NFET region of a substrate, where the first n-type doped epitaxial semiconductor material is wrapped around the first raised feature, selectively depositing a first contact metal on the first n-type doped epitaxial semiconductor material, and annealing the substrate to form a first contact metal silicide on the first n-type doped epitaxial semiconductor material by a salicidation reaction between the first contact metal and the first n-type doped epitaxial semiconductor material. The method further includes growing a second p-type doped epitaxial semiconductor material on a second raised feature in a PFET region of the substrate, where the second p-type doped epitaxial semiconductor material is wrapped around the second raised feature, selectively depositing a second contact metal on the second p-type doped epitaxial semiconductor material, and annealing the substrate to form a second contact metal silicide on the second p-type doped epitaxial semiconductor material by a salicidation reaction between the second contact metal and the second p-type doped epitaxial semiconductor material.

### BRIEF DESCRIPTION OF THE DRAWINGS

In the accompanying drawings:

FIGS. 1A-1AC schematically show through cross-sectional views a method of forming a semiconductor device containing dual silicides according to an embodiment of the invention;

FIGS. 2A-2D schematically show through cross-sectional views a method of forming a semiconductor device containing dual silicides according to an embodiment of the invention; and

FIGS. 3A-3D schematically show through cross-sectional views a method of forming a semiconductor device containing dual silicides according to an embodiment of the invention.

### DETAILED DESCRIPTION OF SEVERAL EMBODIMENTS

A method for forming a semiconductor device is described in several embodiments of the invention. Maximizing the contact area in FinFET structures can be achieved by creating a contact that wraps around the fin or by growing faceted epitaxial contacts, and then wrapping metal around the faceted epitaxial contact. In order to reduce spreading resistance in FinFET structures, wrap around contact (WAC) structures use metal-semiconductor contacts with increased area.

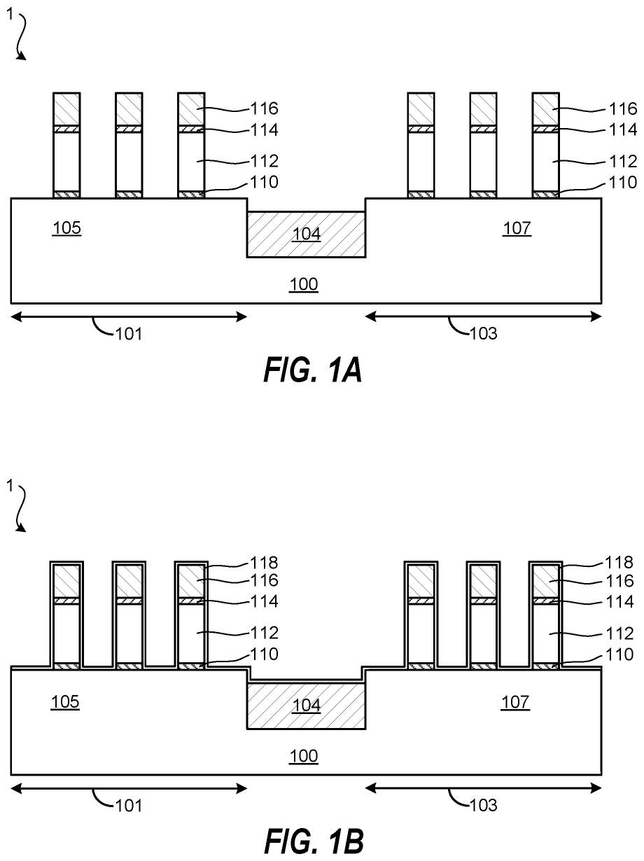

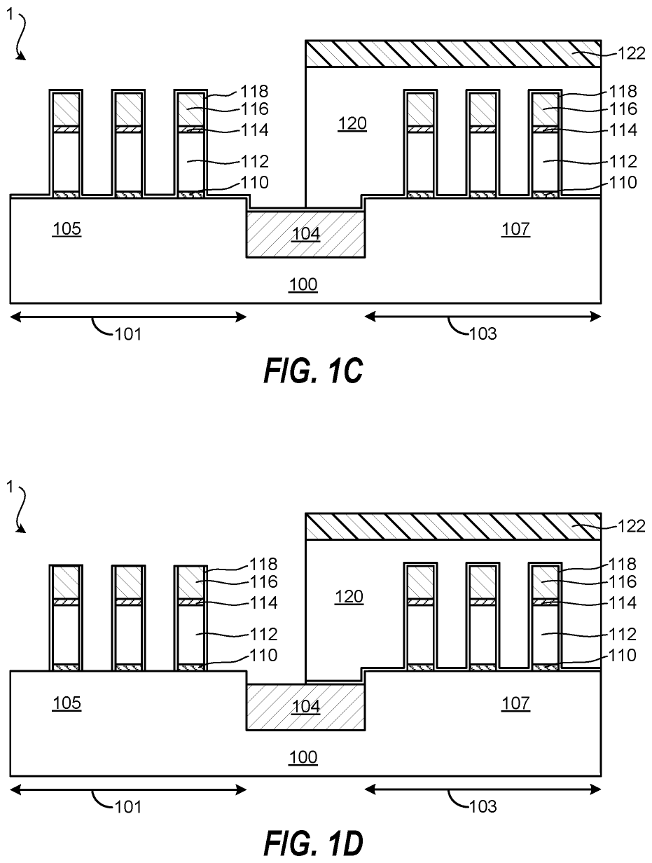

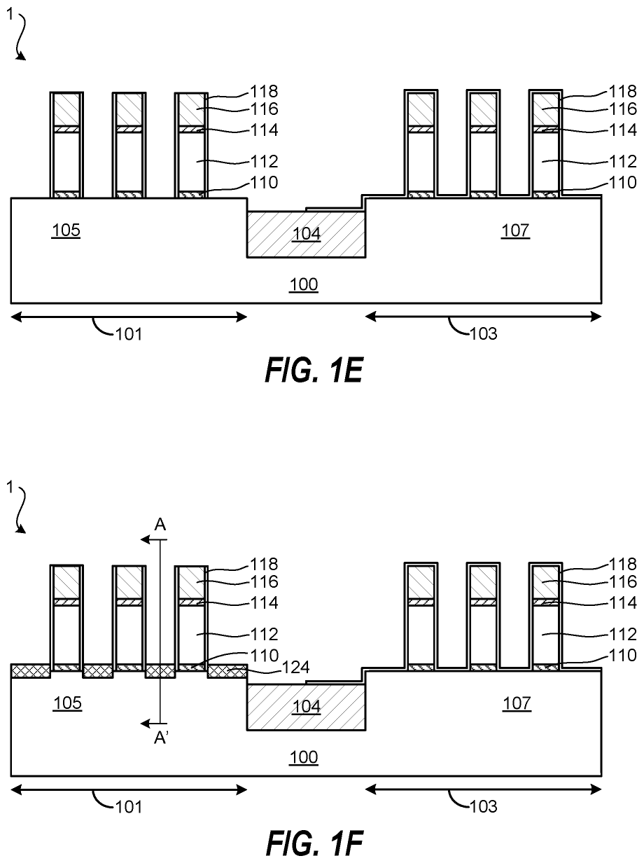

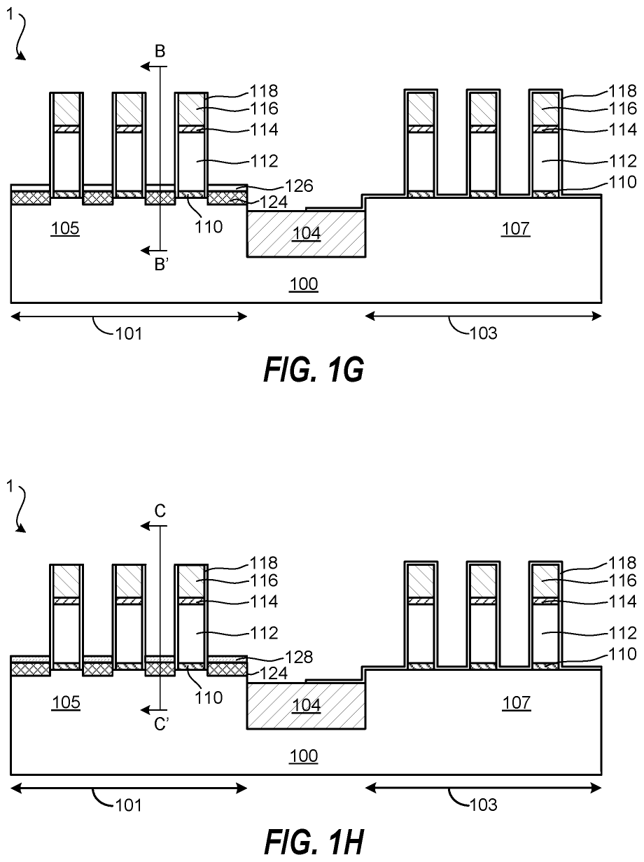

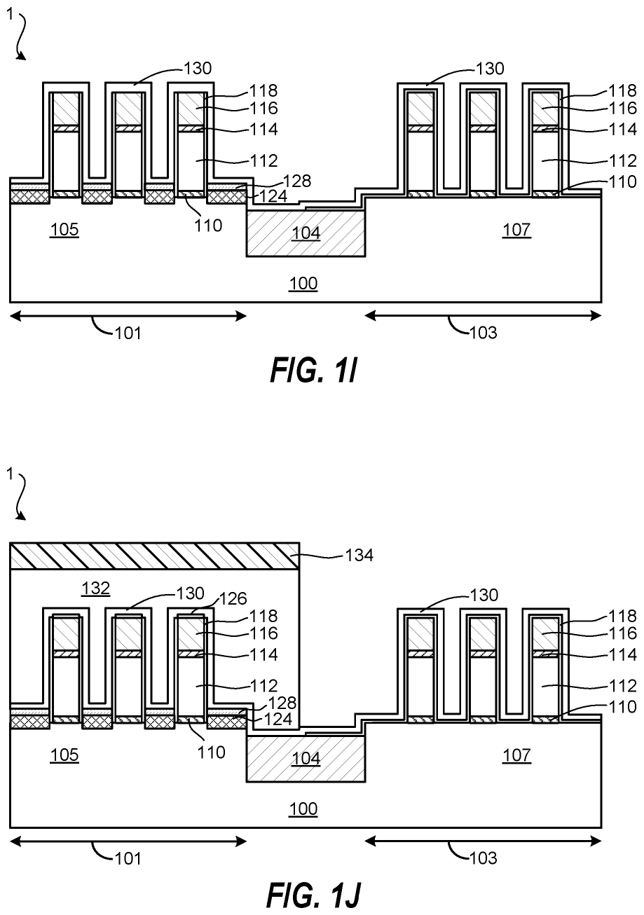

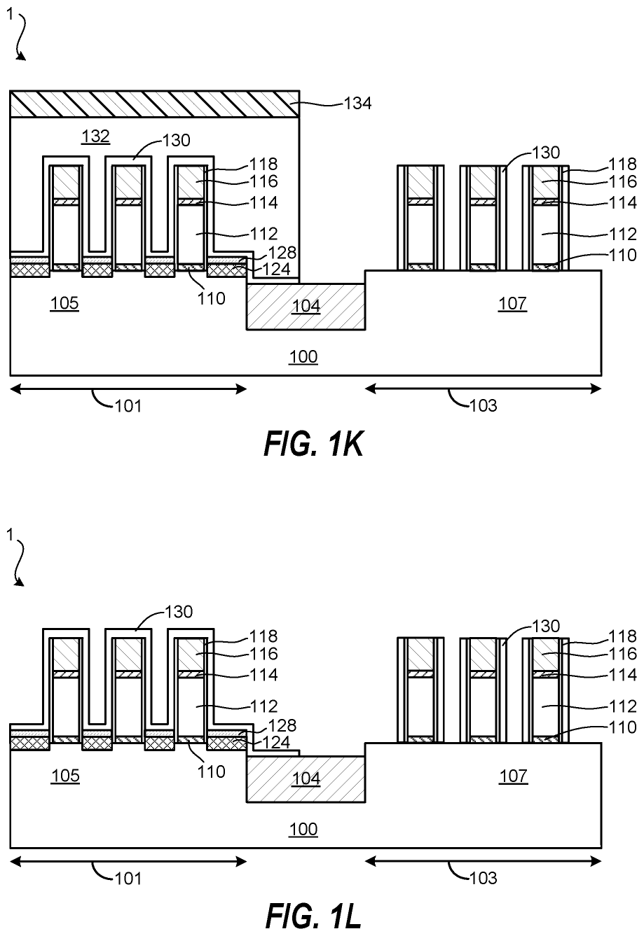

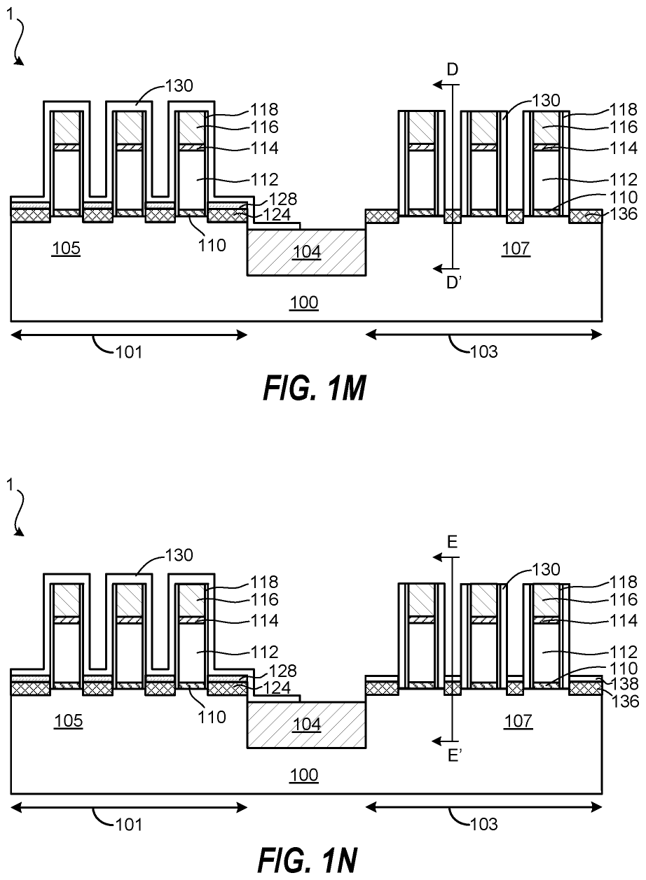

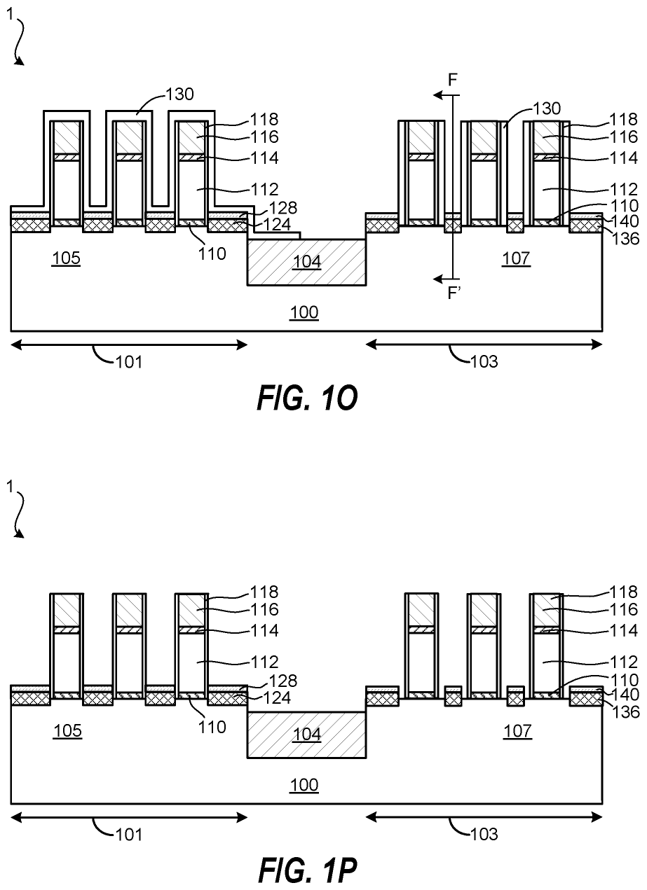

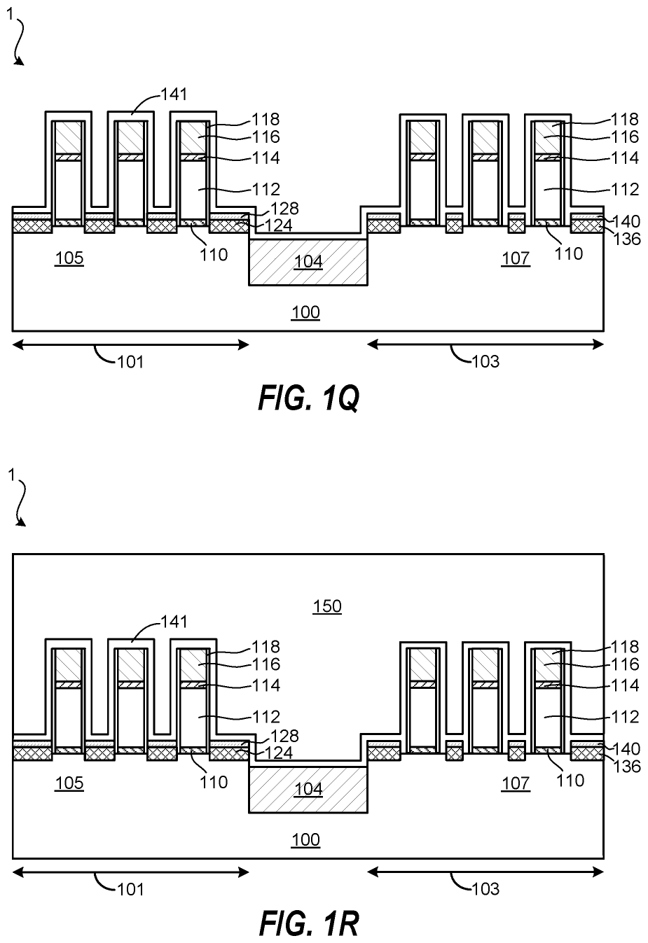

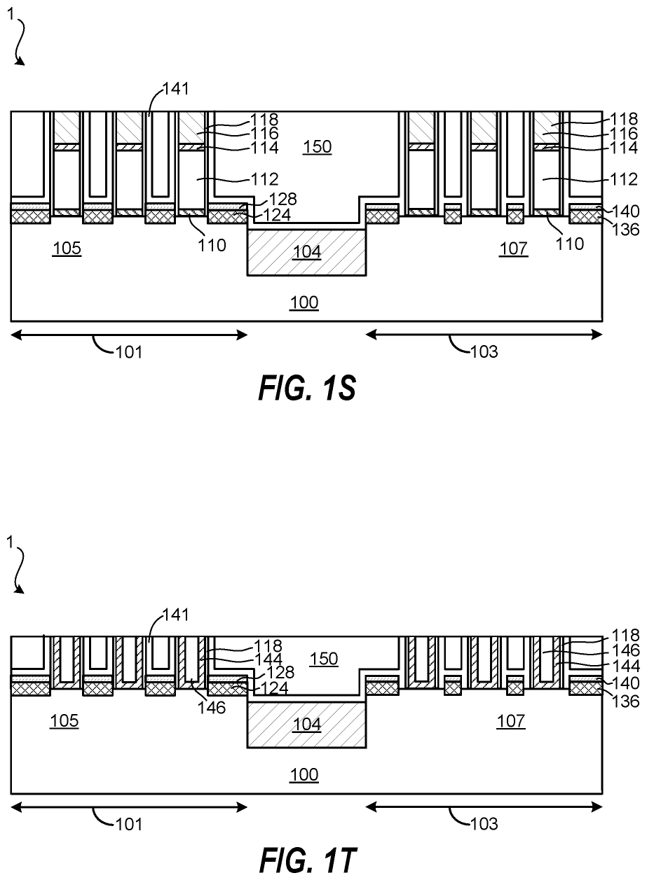

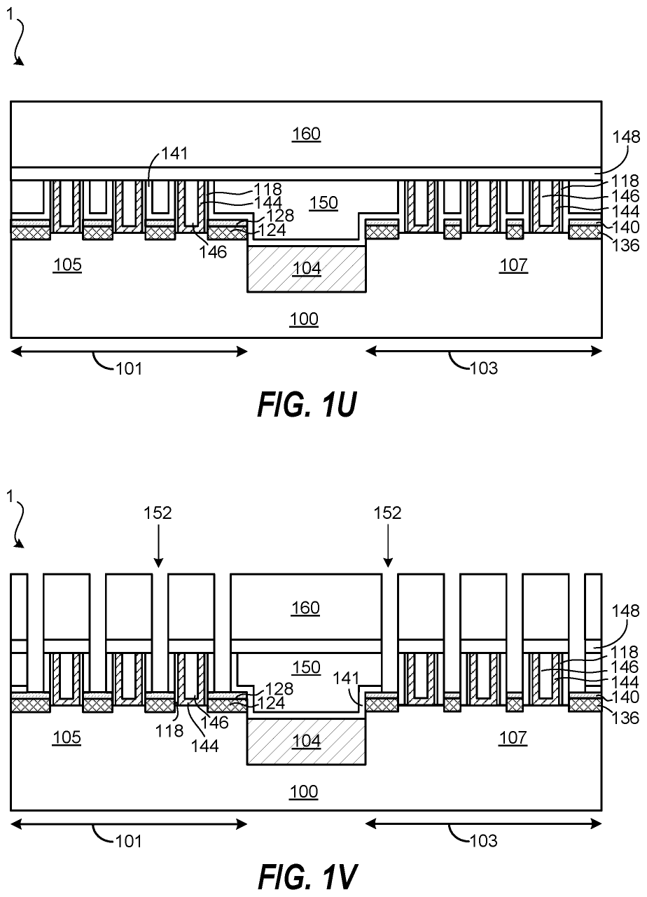

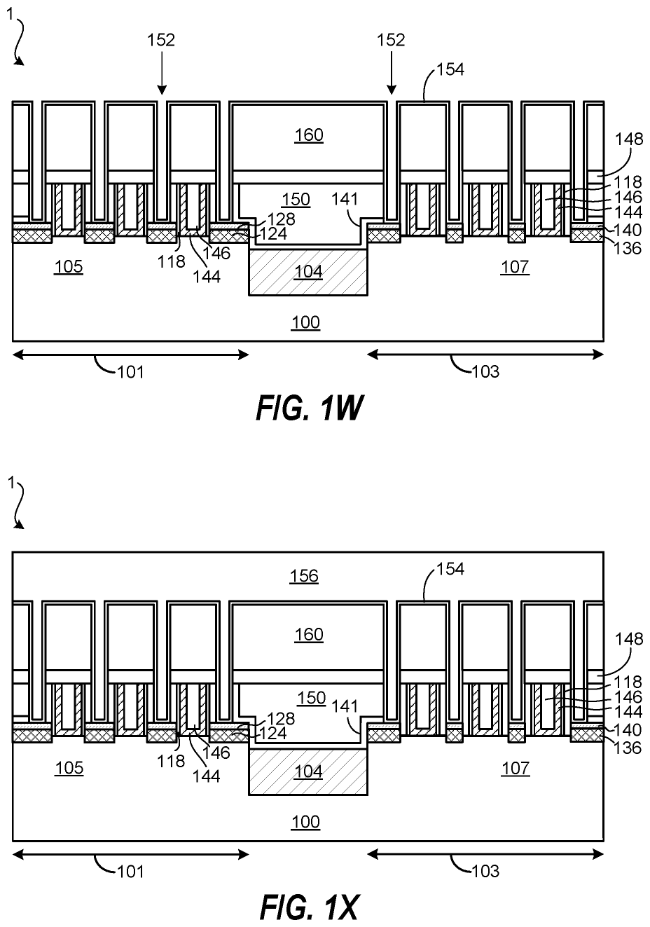

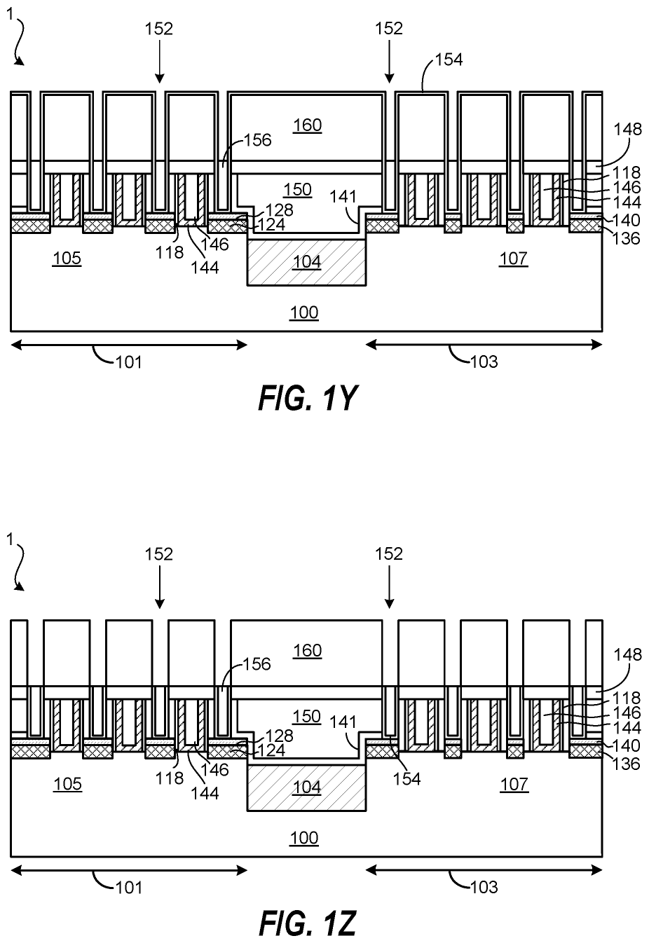

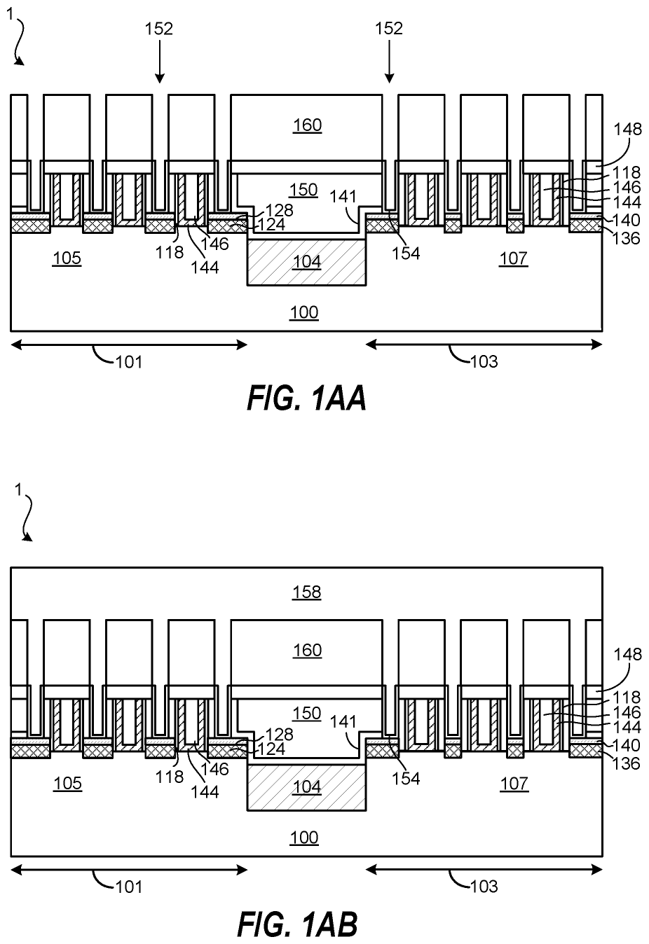

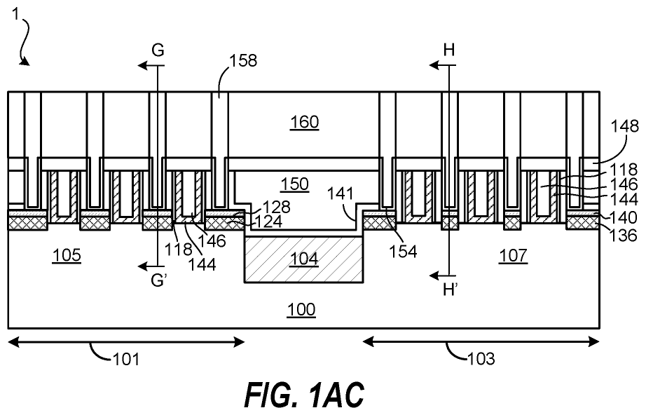

FIGS. 1A-1AD schematically show through cross-sectional views a method of forming a semiconductor device containing dual source drain silicides according to an embodiment of the invention. FIG. 1A schematically shows a substrate 1 containing a base layer 100 that forms a raised feature 105 in a NFET region 101 and a raised feature 107 in a PFET region 103. The base layer 100 can consist of Si and and a shallow trench isolation (STI) region 104 separating the NFET region 101 and the PFET region 103 can include silicon oxide (SiO₂). The substrate 1 further contains three patterned film stacks in each of the NFET region 101 and the PFET region 103. The patterned film stacks each include a sacrificial SiO₂ film 110, a dummy polycrystalline-Silicon (poly-Si) film 112, a SiO₂ hard mask 114, and a silicon nitride (SiN) hard mask 116. The number of the patterned film stacks in FIG. 1A is exemplary and any number of patterned film stacks may be used. The patterned films may be formed using conventional lithography and etching methods.

FIG. 1B shows a low-k gate spacer layer 118 that is conformally deposited on the substrate 1, where the low-k gate spacer layer 118 can, for example, include SiCO or SiBCN materials. FIG. 1C shows an organic layer 120 that is deposited and patterned to cover the PFET region 103 using a patterned photoresist layer 122. In some examples, the organic layer 120 can include an organic planarization layer (OPL) or an organic dielectric layer (ODL). FIG. 1D shows the substrate 1 following a reactive etching process (RIE) that removes horizontal portions of the low-k gate spacer layer 118 in the NFET region 101, while the low-k spacer layer 118 in the PFET region 103 is protected from the RIE by the organic layer 120. The remaining vertical portions of the low-k gate spacer layer 118 form sidewall spacers on the patterned film stacks in the NFET region 101. FIG. 1E shows the substrate 1 following removal of the organic layer 120 and the patterned photoresist layer 122 from the PFET region 103.

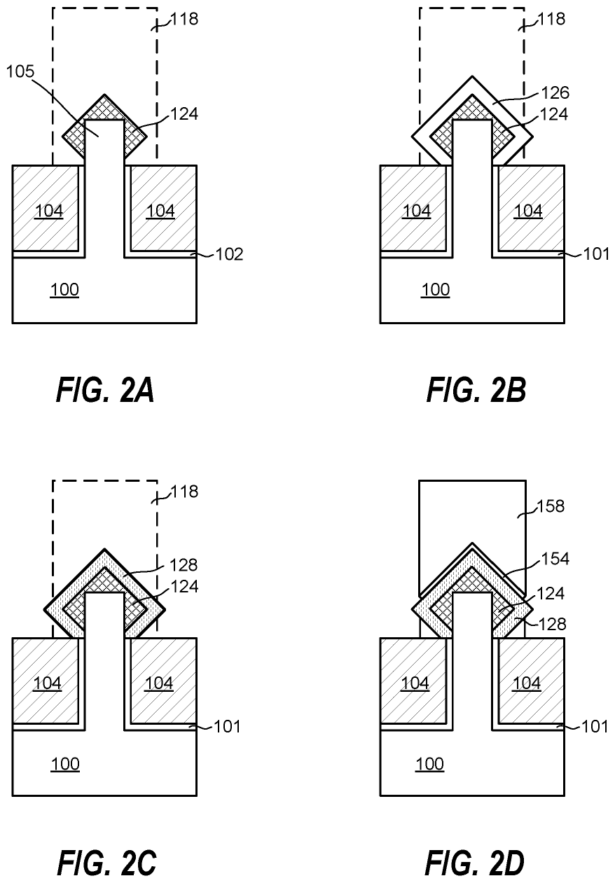

FIG. 1F shows the substrate 1 following selective deposition of a first n-type doped epitaxial semiconductor material 124 on exposed surfaces of the first raised feature 105 (e.g., Si fin) in the NFET region 101. The first n-type doped epitaxial semiconductor material 124 can, for example, contain n-type doped Si that includes phosphor-doped silicon (Si:P) or arsenic-doped silicon (Si:As). FIG. 2A shows a cross-sectional view along the line A-A′ of FIG. 1F. The selective epitaxial deposition results in the first n-type doped epitaxial semiconductor material 124 being faceted and wrapping around the first raised feature 105, where the first n-type doped epitaxial semiconductor material 124 has upward facing surfaces and downward facing surfaces. A liner 102 separates the STI 104 from the first raised feature 105. Selective Si:P epitaxial deposition can be performed using SiH₄, Si₂H₆, or SiH₂Cl₂ and PH₃. Selective Si:As epitaxial deposition can be performed using SiH₄, Si₂H₆ or SiH₂Cl₂ and AsH₃. The selective epitaxial deposition may be performed using a substrate temperature between about 400° C. and about 800° C.

FIG. 1G shows the substrate 1 following selective deposition of a first metal layer 126 on the first n-type doped epitaxial semiconductor material 124. In one example, the first metal layer 126 can include titanium (Ti) metal. FIG. 2B shows a cross-sectional view along the line B-B′ of FIG. 1G. The first metal layer 126 wraps around the first n-type doped epitaxial semiconductor material 124. Selective Ti metal depositing can be performed using TiCl₄ gas flow and pulsed RF plasma.

FIG. 1H shows the substrate 1 following formation of a first metal silicide contact layer 128 in salicide process from a reaction of the first metal layer 126 with the first n-type doped epitaxial semiconductor material 124. In one example, Ti from the first metal layer 126 reacts with Si from the first n-type doped epitaxial semiconductor layer 124 to form TiSi₂, where the low-resistivity C54 phase of TiSi₂ is preferably formed. In the example of TiSi₂, the salicide process can include thermal annealing at substrate temperature between about 750° C. and about 800° C. FIG. 2C shows a cross-sectional view along the line C-C′ of FIG. 1H, where the first metal silicide contact layer 128 wraps around the first n-type doped epitaxial semiconductor material 124.

FIG. 1I shows the substrate 1 following conformal deposition of a SiN liner 130 over the raised and recessed features of the substrate 1, and FIG. 1J shows an organic layer 132 that is patterned to cover the NFET region 101 using a patterned photoresist layer 134. In some examples, the organic layer 132 can include an OPL or an ODL. FIG. 1K shows the substrate 1 following a ME that removes horizontal portions of the SiN liner 130 in the PFET region 103, while the SiN liner 130 in the NFET region 103 is protected from the ME. The remaining vertical portions of the SiN liner 130 form sidewall spacers on the patterned film stacks in the PFET region 103. FIG. 1L shows the substrate 1 following removal of the organic layer 132 and the patterned photoresist layer 134 from the NFET region 101.

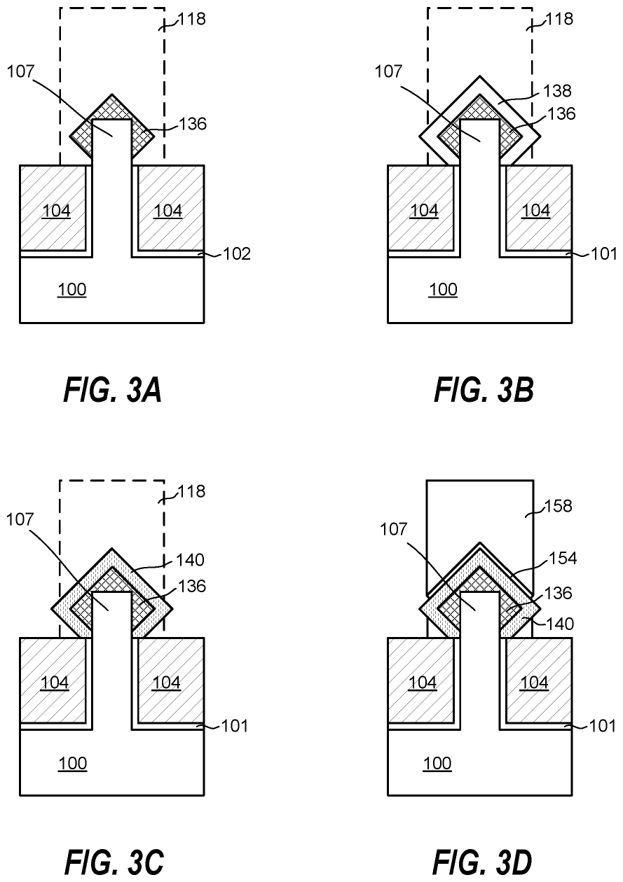

FIG. 1M shows the substrate 1 following selective deposition of a second p-type doped epitaxial semiconductor material 136 on exposed surfaces of the second raised feature 107 (e.g., Si fin) in the PFET region 103. The second p-type doped epitaxial semiconductor material 136 can, for example, contain p-type Si that includes boron-doped silicon (Si:B) or p-type silicon germanium that includes boron-doped silicon germanium (SiGe:B). FIG. 3A shows a cross-sectional view along the line D-D′ of FIG. 1M. The selective epitaxial deposition results in the second doped epitaxial semiconductor material 136 wrapping around the second raised feature 107, where the second p-type doped epitaxial semiconductor material 136 has upward facing surfaces and downward facing surfaces. A liner 102 separates the STI 104 from the second raised feature 107. Selective Si:B epitaxial deposition can be performed using SiH₄, Si₂H₆, or SiH₂Cl₂ and BH₃ or B₂H₆. Selective SiGe:B epitaxial deposition can be performed using SiH₄, Si₂H₆, or SiH₂Cl₂ and GeH₄ and BH₃ or B₂H₆.

FIG. 1N shows the substrate 1 following selective deposition of a second metal layer 138 on the second p-type doped epitaxial semiconductor material 136. In one example, the second metal layer 138 can include ruthenium (Ru) metal. In other examples, the second metal layer 138 can include rhodium (Rh) metal, palladium (Pd) metal, osmium (Os) metal, iridium (Ir) metal, or platinum (Pt) metal. FIG. 3B shows a cross-sectional view along the line E-E′ of FIG. 1N. The second metal layer 138 wraps around the second p-type doped epitaxial semiconductor material 136. In one example, a Ru metal layer 138 with a thickness of about 1-3 nm may be selectively deposited by chemical vapor deposition (CVD) using a process gas containing Ru₃(CO)₁₂ and CO.

FIG. 1O shows the substrate 1 following formation of a second metal silicide contact layer 140 in salicide process from a reaction of the second metal layer 138 with the second p-type doped epitaxial semiconductor material 136. In one example, Ru from the second metal layer 138 reacts with Si from the second p-type doped epitaxial semiconductor layer 136 to form a ruthenium silicide (RuSiₓ). In the example of a ruthenium silicide, the salicide process can include thermal annealing at substrate temperature between about 350° C. and about 500° C. FIG. 3D shows a cross-sectional view along the line F-F′ of FIG. 1O, where the second metal silicide contact layer 140 wraps around the second p-type doped epitaxial semiconductor material 136.

FIG. 1P shows the substrate 1 following removal of the SiN liner 130 from the NFET region 105 and from the PFET region 107, and FIG. 1Q shows conformal deposition of a SiN liner 41 over the raised and recessed features of the substrate 1. FIG. 1R shows the substrate 1 following blanket deposition of a gap-fill oxide film 150, were the gap-fill oxide film 150 may be deposited using a flowable oxide and a SiH₄-based oxide, for example. FIG. 1S shows the substrate 1 following a planarization process that stops on the SiN hard mask 116. In one example, the planarization process can include CMP.

FIG. 1T shows the substrate 1 following removal of the patterned film stacks and replacement with a high-k layer 144 and a metal gate layer 146. FIG. 1U shows the substrate 1 following deposition of a SiN liner 148 and an interlayer dielectric (ILD) 160 on the SiN liner 148. Thereafter, as shown in FIG. 1V, a self-aligned contact etching process is performed to form recessed features 152 down to the first metal silicide contact layer 128 in the NFET region 101 and down to the second metal silicide contact layer 140 layer in the PFET region 103.

Thereafter, as shown in FIG. 1W, a titanium nitride (TiN) layer 154 is conformally deposited on the substrate 1, including in the recessed features 152. In one example, the TiN layer 154 can have a thickness of less than about 3 nm. FIG. 1X shows the substrate 1 following blanket deposition of an organic layer 156. In some examples, the organic layer 156 can include an OPL or an ODL. Thereafter, as shown in FIG. 1Y, the organic layer 156 is partially removed from the recessed features 152 by terminating an etching process before the organic layer 156 is fully removed from the recessed features 152.

FIG. 1Z shows the substrate 1 following removal of the TiN layer 154 above the organic layer 156 in the recessed features 152. The removal may be complete as schematically shown in FIG. 1Z or, alternatively, the removal may only thin the TiN layer 154 above the organic layer 156 in the recessed features 152. Thereafter, as shown in FIG. 1AA, the remainder of the organic layer 156 is removed from the recessed features 152.

FIG. 1AB shows the substrate 1 following a metal gap fill process that fills the recessed features 152 with a metal 158 (e.g., Co metal or Ru metal). FIG. 1AC shows the substrate 1 following a planarization process that removes excess metal (overburden). In one example, the planarization process can include CMP. FIG. 2D shows a cross-sectional view along the line G-G′ of FIG. 1AD and FIG. 3D shows a cross-sectional view along the line H-H′ of FIG. 1AD.

A plurality of embodiments for low-resistivity dual silicide contacts in aggressively scaled devices have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A semiconductor device, comprising:
a first raised feature in a n-type channel field effect transistor (NFET) region on a substrate;
a first n-type doped epitaxial semiconductor material wrapped around the first raised feature;
a first metal silicide contact layer wrapped around the first n-type doped epitaxial semiconductor material;
a second raised feature in p-type channel field effect transistor (PFET) region on the substrate;
a second p-type epitaxial semiconductor material wrapped around the second raised feature; and
a second metal silicide contact layer wrapped around the second p-type doped epitaxial semiconductor material.

2. The device of claim 1, wherein the first and second raised features contain Si fins.

3. The device of claim 1, wherein the first n-type doped epitaxial semiconductor material contains Si:P or Si:As.

4. The device of claim 1, wherein the second p-type doped epitaxial semiconductor material contains Si:B or SiGe:B.

5. The device of claim 1, wherein the first and second doped epitaxial materials each have upward facing surfaces and downward facing surfaces, and the first and second metal silicide contact layers are formed on the upward facing surfaces and on the downward facing surfaces.

6. The device of claim 1, wherein the first metal silicide contact layer includes a titanium silicide and the second metal silicide contact layer contains a silicide of ruthenium (Ru), rhodium (Rh), palladium (Pd), osmium (Os), iridium (Ir), or platinum (Pt).

7. The device of claim 1, further comprising:
a titanium nitride (TiN) layer directly on the first silicide contact layer and on the second metal silicide contact layer; and
a cobalt metal layer or a ruthenium metal layer on the TiN layer.

8. A semiconductor device, comprising:
a first raised Si feature in a n-type channel field effect transistor (NFET) region on a substrate;
a first n-type doped epitaxial semiconductor material wrapped around the first raised Si feature, the first doped epitaxial semiconductor material containing Si:P or Si:As;
a titanium silicide contact layer wrapped around the first n-type doped epitaxial semiconductor material;
a second raised Si feature in p-type channel field effect transistor (PFET) region on the substrate;
a second p-type doped epitaxial semiconductor material wrapped around the second raised feature, the second p-type epitaxial semiconductor material containing Si:B or SiGe:B; and
a ruthenium silicide contact layer wrapped around the second p-type doped epitaxial semiconductor material.

9. The device of claim 8, wherein the first and second doped epitaxial materials each have upward facing surfaces and downward facing surfaces, and the titanium silicide contact layer and the ruthenium silicide contact layer are formed on the upward facing surfaces and on the downward facing surfaces.

10. The device of claim 8, further comprising:
a titanium nitride (TiN) layer directly on the titanium silicide contact layer and on the ruthenium silicide contact layer; and
a cobalt (Co) metal layer or a ruthenium (Ru) metal layer on the TiN layer.

11. A method of forming a semiconductor device, the method comprising:
growing a first n-type doped epitaxial semiconductor material on a first raised feature in a n-type channel field effect transistor (NFET) region of a substrate, wherein the first n-type doped epitaxial semiconductor material is wrapped around the first raised feature;
selectively depositing a first metal layer on the first n-type doped epitaxial semiconductor material;
annealing the substrate to form a first metal silicide contact layer on the first n-type doped epitaxial semiconductor material by a salicidation reaction between the first contact metal and the first n-type doped epitaxial semiconductor material;
growing a second p-type doped epitaxial semiconductor material on a second raised feature in a p-type channel field effect transistor (PFET) region of the substrate;
selectively depositing a second metal layer on the second p-type doped epitaxial semiconductor material; and
annealing the substrate to form a second metal silicide contact layer on the second p-type doped epitaxial semiconductor material by a salicidation reaction between the second contact metal and the second p-type doped epitaxial semiconductor material.

12. The method of claim 11, wherein the first and second raised features contain Si.

13. The method of claim 11, wherein the first n-type doped epitaxial semiconductor material contains Si:P or Si:As.

14. The device of claim 11, wherein the second p-type doped epitaxial semiconductor material contains Si:B or SiGe:B.

15. The method of claim 11, wherein the first and second doped epitaxial materials each have an upward facing surface and a downward facing surface.

16. The method of claim 11, wherein the first metal layer includes titanium metal and the second metal layer includes ruthenium metal.

17. The method of claim 11, wherein the first metal silicide contact layer includes a titanium silicide and the second metal silicide contact layer contains a silicide of ruthenium (Ru), rhodium (Rh), palladium (Pd), osmium (Os), iridium (Ir), or platinum (Pt).

18. The method of claim 11, further comprising:
a titanium nitride (TiN) layer directly on the first metal silicide contact layer and on the second metal silicide contact layer; and
a cobalt (Co) metal layer or a ruthenium (Ru) metal layer on the TiN layer.

19. The method of claim 11, wherein the first and second raised features contain Si, the first n-type doped epitaxial semiconductor material contains Si:P or Si:As, the second p-type doped epitaxial semiconductor material contains Si:B or SiGe:B, the first metal silicide contact layer includes a titanium silicide, and the second metal silicide contact layer includes a ruthenium silicide.

20. The method of claim 11, wherein the first and second doped epitaxial materials each have an upward facing surface and a downward facing surface.
